(19) United States
(12) Patent Application Publication
(10) Pub. No.: US 2020/0048770 A1
(43) Pub. Date: Feb. 13, 2020

(54) CHEMICAL VAPOR DEPOSITION TOOL FOR PREVENTING OR SUPPRESSING ARCING

(71) Applicant: Lam Research Corporation, Fremont, CA (US)

(72) Inventors: Yukinori SAKIYAMA, West Linn, OR (US); Karl Frederick LEESER, West Linn, OR (US); Vincent BURKHART, Cupertino, CA (US)

(21) Appl. No.: 16/057,383

(22) Filed: Aug. 7, 2018

(51) Int. Cl. C23C 16/52; H01J 37/32; C23C 16/505

(52) U.S. Cl. CPC C23C 16/52; H01J 37/32174; H01J 37/32697; H01J 2237/0206; C23C 16/505; H01J 2237/24564; H01J 2237/3321; H01J 37/32715

(57) ABSTRACT

A Chemical Vapor Deposition (CVD) tool that suppresses or altogether eliminates arcing between a substrate pedestal and substrate. The CVD tool includes a Direct Current (DC) bias control system arranged to maintain a substrate pedestal provided in a processing chamber at a same or substantially the same DC bias voltage as developed by a plasma in the processing chamber. By maintaining the substrate pedestal and the substrate having the same potential as the plasma at the same or substantially the same voltage potential, arcing is suppressed or altogether eliminated.

### BACKGROUND

Plasma Enhanced Chemical Vapor Deposition (PECVD) tools are used for depositing thin films on substrates. A CVD tool typically includes a processing chamber, a substrate pedestal for supporting a substrate in the processing chamber, and a shower head. During operation, the shower head distributes a reactant gas above the surface of the substrate to be processed. A Radio Frequency (RF) potential is applied between two electrodes, typically provided on the shower head and/or the substrate pedestal, to generate a plasma. Energized electrons ionize or dissociate (e.g., “crack”) reactant gasses from the plasma, creating chemically reactive radicals. As these radicals react, they deposit and form a thin film on the substrate.

Arcing is a well known electrical phenomenon caused by a breakdown of an ordinarily non-conductive gas provided in a gap between two surfaces at different voltage potentials. When arcing occurs, the non-conductive gas breaks down and a strong electrical current or discharge briefly jumps across the gap between two surfaces.

With PECVD tools, arcing is a significant problem. Electrically resistive materials (e.g. dielectric film) are typically provided between the substrate and the pedestal. During operation of the tool, the plasma and substrate in the processing chamber inherently develops a Direct Current (DC) bias voltage when the RF potential is applied. As a result, a non-zero DC voltage exists between the substrate and the substrate pedestal due to the resistive materials.

If the difference in the DC voltage exceeds a certain threshold, electrical breakdown may occur in the gas between the substrate and the substrate pedestal. As thin films are deposited on substrates, the magnitude of DC bias voltage tends to increased. As a result, the probability of electrical breakdown significantly increases. With certain types of substrates, such as semiconductor wafers, sudden bursts of electrical discharge or arcing can destroy sensitive circuitry. The destruction of circuitry on a semiconductor wafer reduces yields, resulting in potentially significant manufacturing losses and increased costs.

A CVD tool that suppresses or altogether eliminates arcing between a substrate and substrate pedestal is therefore needed

### SUMMARY

A Chemical Vapor Deposition (CVD) tool that suppresses or altogether eliminates arcing between a substrate pedestal and substrate is disclosed. The tool includes a processing chamber, a substrate pedestal for supporting a substrate within the processing chamber, and shower head positioned within the processing chamber. The shower head is arranged to dispense gas that is turned into a plasma, which develops a DC bias voltage in response to a Radio Frequency (RF) potential. The tool also includes a Direct Current (DC) bias control system arranged to maintain the substrate pedestal at a same or substantially the same DC bias voltage as the DC bias voltage developed by the plasma.

In a non-exclusive embodiment, the DC bias control system adjusts the DC bias voltage of the substrate pedestal by measuring DC current between the plasma and the substrate pedestal and maintaining the DC current at constant when the resistance between ground and the substrate is kept constant.

In another non-exclusive embodiment, the DC bias control system is further arranged to measure DC current at the start of the processing of a substrate and then adjust the DC bias voltage to maintain the measured DC current for the remainder of the substrate processing in order to compensate the drift of the resistance.

In various non-exclusive embodiments, the current path between the plasma and the electrode includes one or more of the following (a) the substrate supported by the substrate pedestal, (b) any thin film(s) formed on the substrate (c) the substrate pedestal, (d) a power supply couple to the substrate pedestal. The resistance consists of one or more of the following (f) the substrate, (g) any thin film(s) formed on the substrate, (h) the substrate pedestal and (i) resistive component in a power supply system couple to the substrate pedestal.

### BRIEF DESCRIPTION OF THE DRAWINGS

The present application, and the advantages thereof, may best be understood by reference to the following description taken in conjunction with the accompanying drawings in which:

FIG. 1 is a block diagram of a Chemical Vapor Deposition (CVD) chamber in accordance with a non-exclusive embodiment of the invention.

FIG. 2A and FIG. 2B are a top-down and cross-sectional views of a substrate pedestal in accordance with a non-exclusive embodiment of the invention.

FIG. 3 is a diagram illustrating how arcing is suppressed or prevented in accordance with a non-exclusive embodiment of the invention.

FIG. 4 is a plot illustrating the unpredictability of the DC bias voltage developed by plasma in a tool over time.

FIG. 5 is a block diagram illustrating an active DC bias control system for a substrate pedestal in accordance with the present invention.

FIG. 6 is a diagram of a CVD chamber having multiple substrate pedestals in accordance with a non-exclusive embodiment of the invention.

FIG. 7 is a block diagram of a system controller used for controlling a CVD tool in accordance with a non-exclusive embodiment of the invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

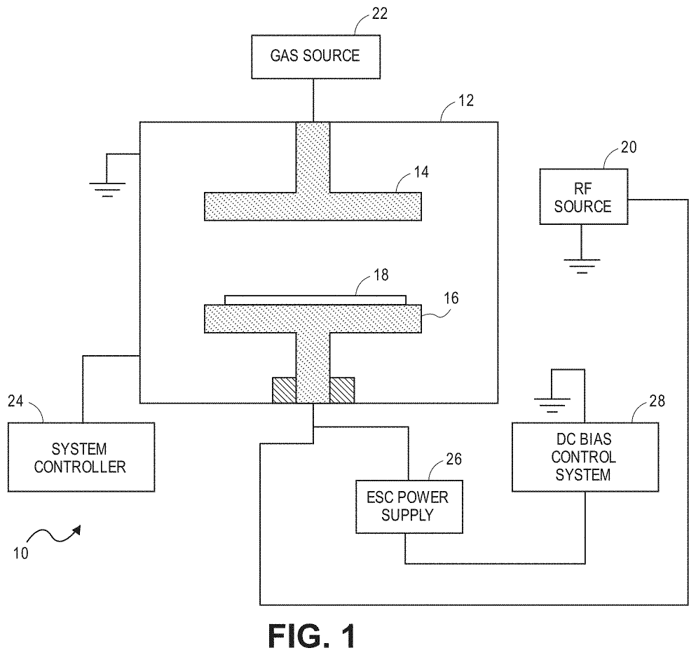

Referring to FIG. 1, a block diagram of a Chemical Vapor Deposition (CVD) tool 10 is illustrated. The tool 10 includes a processing chamber 12, a shower head 14, a substrate pedestal 16 for positioning a substrate 18 to be processed, a Radio Frequency (RF) source generator 20, a gas source 22, a system controller 24, an ESC power supply 26 coupled to the substrate pedestal 16 and a Direct Current (DC) bias control system 28. In various embodiments, the CVD tool may be Plasma Enhanced (PECVD), Plasma-Enhanced Atomic Layer Deposition (PEALD) or any other type of CVD tool that uses a plasma.

During operation, reactant gas(es) are supplied from the gas source 22 into the processing chamber 12 through the shower head 14. Within the shower head 14, the gas(es) is/are distributed via one or more plenums (not illustrated) into the chamber 12 in the area above the surface of the substrate 18. An RF potential, generated by the RF generator 20, is applied to one or more electrode(s) (not visible) on the substrate pedestal 16. The RF potential causes the gas to ionize and generate a plasma inside the processing chamber 12. Within the plasma, energized electrons dissociate (i.e., “crack”) from the reactant gas(es), creating chemically reactive radicals. As these radicals react, they deposit and form a thin film on the substrate 18.

In various embodiments, the RF generator 20 may be a single RF generator or multiple RF generators capable of generating high, medium and/or low RF frequencies. For example, in the case of high frequencies, the RF generator 20 may generate frequencies ranging from 2-100 MHz and preferably 13.56 MHz or 27 MHz. When low frequencies are generated, the range is 50 KHz to 2 MHz, and preferably 350 to 600 KHz. In alternative embodiments, the RF source may be coupled to an RF electrode provided on the shower head 14 instead of the substrate pedestal 16 or both the shower head 14 and substrate pedestal 16.

The system controller 24 is used to control the overall operation of the CVD tool 10 in general and manage process conditions during deposition, post deposition, and/or other process operations.

In a non-exclusive embodiment, the substrate pedestal 16 is an Electrostatic Chucking (ESC) type substrate pedestal. The ESC power supply 26 is provided to supply to electrodes (not shown in FIG. 1), embedded in a clamping surface of the substrate pedestal 16, opposing voltages of a magnitude sufficient to generate an electrostatic force required to clamp the substrate 18.

When the RF potential is applied with reactant gas(es) in the processing chamber 12, a plasma results. The plasma develops a DC bias, typically in the range of (0) to (−100) volts, in response to the RF potential. With the substrate 18 exposed to the plasma, the substrate develops the same or substantially the same DC bias voltage as the plasma. Ordinarily the substrate pedestal 16 is typically maintained at a different voltage. The voltage differential between the substrate pedestal 16 and the substrate 18 susceptible to arcing.

DC bias control system 28 is provided to maintain the substrate pedestal 16 at the same or substantially the same DC bias voltage as developed by the plasma and substrate 18. The voltage differential between the substrate pedestal 16 and the substrate 18 is therefore zero or close to zero. As a result, arcing between the substrate pedestal 16 and the substrate 18 is suppressed or all together eliminated.

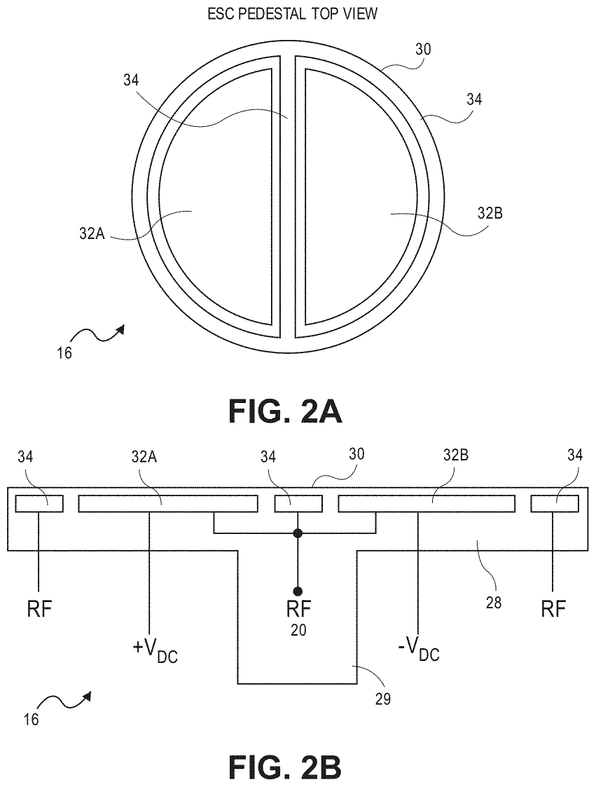

Referring to FIG. 2A and FIG. 2B, top-down and cross-sectional views of a non-exclusive embodiment of the substrate pedestal 16 is shown. In this particular embodiment, the body 29 of the substrate pedestal 16 is made from a non-conductive ceramic material, such as Aluminum Nitride. An Electrostatic Chucking (ESC) surface 30, for clamping the substrate 18, is embedded into the substrate pedestal 16.

As best illustrated in FIG. 2A, the electrode 30 is embedded into the substrate pedestal 16 and includes a pair of “D-shaped” ESC clamping electrodes 32A and 32B. During clamping, a voltage of opposite polarity (e.g., +/−500 volts) is provided to the two electrodes 32A and 32B respectively. The resulting electrostatic forces clamp the substrate 18 to the clamping surface 30 of the substrate pedestal 16.

The substrate pedestal 16 also includes an RF electrode 34 that is embedded in and provided around the periphery and through the center of the top surface 30. The electrodes 32A, 32B, and 34 are coupled to the RF source 20 and are arranged to provide the RF potential needed to ionize the reactant gas(es) supplied to the processing chamber 12 and to generate the plasma. As best illustrated in FIG. 2B, the cross section shows the ESC clamping electrodes 32A and 32B and the RF electrode 32A, 32B, and 34 are embedded in the body 29 of the substrate pedestal 16.

To suppress or prevent arcing, the DC bias control system 26 provides a bias voltage to the left and right electrodes 32A and 32B. For instance, consider an ESC clamping voltage of (+/−500 volts) applied to the electrodes 32A and 32B respectively. If the plasma in the processing chamber 12 develops a bias of (−10 volts), then a bias voltage V_{DC} of the same or a similar magnitude is applied to the electrodes 32A and 32B. In other words, electrode 32A is maintained at 490 volts (500−10) and electrode 32B is maintained at −510 volts (−500−10). In another non-exclusive embodiment, the same bias voltage V_{DC} (e.g., −10V) can be applied to the electrode 34 as well.

Since the voltage differential between the two electrodes 32A and 32B remains the same, the bias voltage V_{DC} does not affect the ESC clamping force. However, the voltage differential between the substrate pedestal 16 and the substrate 18 is reduced to zero or very close to zero, suppressing or altogether eliminating arcing.

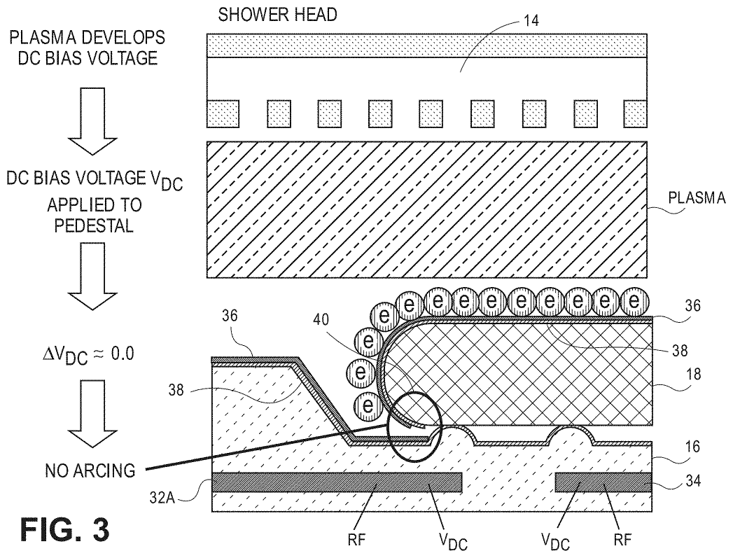

Referring FIG. 3, a diagram showing how arcing is prevented or suppressed is illustrated. The shower head 14 introduces one or more reactant gas(es) into the processing chamber 12. The RF potential, provided by the electrode 34 embedded in the substrate pedestal 16, results the ionization of the reactant gas(es), generating the plasma.

In this particular example, an electrically conductive thin film 36, such as a metal or conductive carbon layer, is deposited over a dielectric layer 38. During the deposition, the layers or films 36, 38 form over both the top surface of the substrate 18 and the surrounding portion of the substrate pedestal 16. As the conductive layer 36 is formed, negative surface charges, designated by the letter “e”, build up on surface of the substrate 18.

A DC bias voltage “V_{DC}”, which is the same as the DC bias voltage developed by the plasma, is applied to the electrodes 32A and 32B (not shown) of the substrate pedestal 16. Since the voltage differential between the substrate 18 and the substrate pedestal 16 is the same or substantially the same, the surfaces charges “e” on the substrate 18 are not attracted to the substrate pedestal 16. As a result, arcing is suppressed or altogether eliminated, particularly in the region depicted by the oval 40, which tends to be the location most susceptible to arcing.

During the processing of substrates 18 in the processing chamber 12, the DC bias voltage developed by the plasma tends to unpredictably vary over time. For example, during the deposition of a conductive (e.g., a carbon) layer onto a semiconductor wafer, the plasma “sees” the conductive layer as an electrode. Over an extended deposition, the layer tends to grow wider and thicker over time on both the wafer and the surrounding top surface of the substrate pedestal 16. As a result of this growth, the plasma tends to spread out, causing the DC bias voltage developed by the plasma to change. The DC bias voltage developed by the plasma, however, is typically not linear. As a result, it is very difficult to predict how the developed DC bias voltage of the plasma will vary over time.

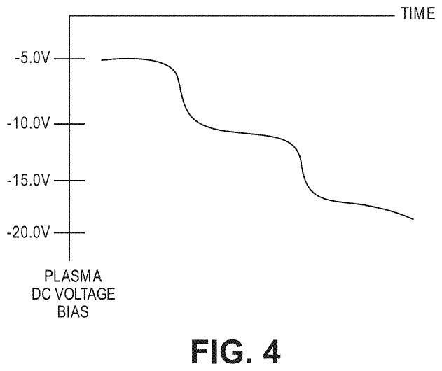

FIG. 4 is an exemplary plot illustrating the unpredictability of the DC bias voltage developed by a plasma in a CVD tool during a deposition. The plot shows that over time, the DC bias voltage tends to decrease (e.g., from approximately −5.0 volts to approximately −20.0 volts). The decrease, however, is not linear. The plot thus shows that if a fixed bias voltage V_{DC} is applied to the electrodes 32A, 32B and/or 34, a voltage differential may exist at times between the substrate 18 and the substrate pedestal 16 as the DC bias voltage of the plasma varies. Whenever a voltage differential exists, the substrate 18 is susceptible to arcing. The plot shown is merely illustrative and is provided to show the non-linearity of the DC bias voltage decrease. It should be understood that in actual embodiments, the plot will widely vary, but will typically show a decrease in the DC bias voltage.

When non-zero voltage difference exists, DC current flows between plasma and grounded electrode due to finite resistance between them. The current path between the plasma and the electrode includes one or more of the following: (a) the substrate 18 supported by the substrate pedestal 16; (b) any thin film(s) formed on the substrate 18; (c) electrodes 32A, 32B and 34 provided on the substrate pedestal 16; (d) the power supply 26 couple to the substrate pedestal 16 and (e) the substrate pedestal 16.

The resistance consists of one or more of the following provided on the above-defined current path: (a) the substrate 18; (b) any thin film(s) formed on the substrate 18; (c) electrodes 32A, 32B and 34 provided on the substrate pedestal 16 and the power supply 26 couple to the substrate pedestal 16.

As conditions within the processing chamber 12 change, the DC bias voltage of a plasma changes as noted above. When the resistance is fixed, changes in the measured current will be indicative of the changes of the DC bias voltage of the plasma. As result, changes in the value of ΔV_{DC} is commensurate with the changes of the DC bias voltage developed by the plasma over time. By continually measuring and applying ΔV_{DC} to the electrodes 32A, 32B, and/or 34, the DC bias voltage of the substrate pedestal can substantially track the DC bias developed by the plasma and substrate 18 as processing conditions change. In other words, the voltage differential between the substrate pedestal 16 and the substrate 18 remain zero or close to zero as conditions in the processing chamber 12 change.

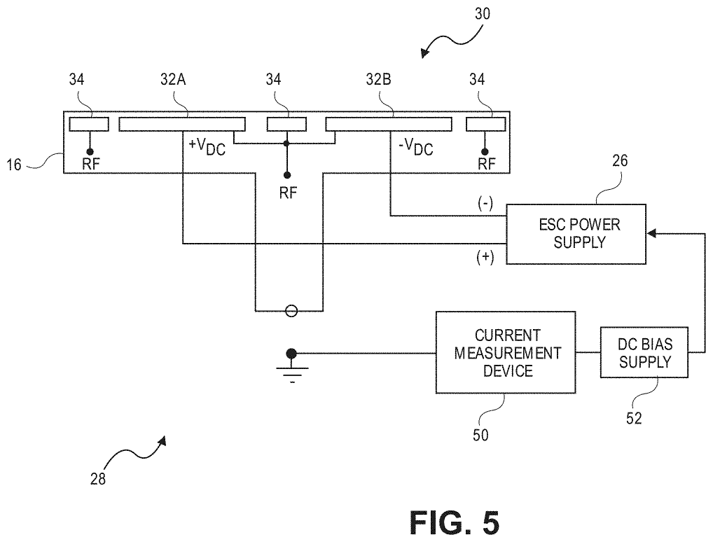

Referring to FIG. 5, a block diagram illustrating of the DC bias control system 28 is illustrated. The system 28 includes a current measurement device 50 and the ESC power supply 26. The current measuring device 50 measures samples of the current between the plasma and a grounded electrode. A DC power supply 52 adjusts the bias voltage applied to the electrodes 32A, 32B, and/or 34 via the ESC power supply 26 to maintain a constant current. By maintaining the constant current, the voltage differential between the substrate 18 and the substrate pedestal at zero or close to zero.

In various embodiments, the predetermined sampling rate for measuring the current samples may widely vary. For example, the sample rate can range anywhere from 1 ms to 10 seconds. In general, the higher the sampling rate, the more precisely the bias voltage can be adjusted to track changes in the actual DC bias developed by the plasma. As a result, a higher degree of arcing suppression is likely to be realized.

Based on the above, there are at number of ways to suppress or altogether prevent arcing. For example:
By maintaining the voltage between the substrate 18 and the substrate pedestal 16 constant (zero or close to zero volts), arcing can be eliminated or significantly limited. However, as the DC bias voltage of the plasma changes over time, the voltage differential between the pedestal and substrate may increase. As a result, the chance of arcing may increase as well.
By using a feedback loop to measure the sampled current and controlling the DC bias supply 52 to adjusts the bias voltage applied to the electrodes 32A, 32B, and/or 34 via the ESC power supply 26, the measured current can be maintained a pre-defined constant value. While this method works even if the DC bias voltage of the plasma changes over time, it is susceptible if the resistance changes. For example, if the resistance changes from one substrate to the next or as layers are added to a substrate, then the possibility of arcing may increase.
Measure the current once and use it as a set point for each substrate. Thereafter, the above-described feedback loop is used to adjust the bias voltage applied to the electrodes 32A, 32B, and/or 34. With the next substrate, the set point is measured again and the bias voltage is adjusted accordingly. By measuring the current for each substrate, the set point is updated to compensate for drift in the system. With this approach, the chance of arching is significantly suppressed, even as the DC bias of the plasma changes and/or conditions in the chamber 12 change over time.

The ability to measure DC current and adjust and apply a DC bias voltage to the electrodes 32A, 32B and/or 34 of the substrate pedestal 16 provides a number of advantages. First, the voltage differential between a substrate pedestal 16 and the substrate 18 remains zero or close to zero for the duration of the time the substrate 18 is processed in the chamber 12. Second, as one substrate 18 is replaced with another for processing, the current can be measured and the DC bias voltage adjusted to match the current conditions in the processing chamber 12. Third, the DC bias control system 28 has the ability to adjust the DC bias voltage regardless of the tool 10 and/or process chamber 12. Accordingly, any variations from one CVD tool 10 to the next, or one processing chamber 12 to the next, is not an issue because the DC bias control system 28 has the ability to adjust the DC bias voltage no matter how conditions may vary from one tool to the next.

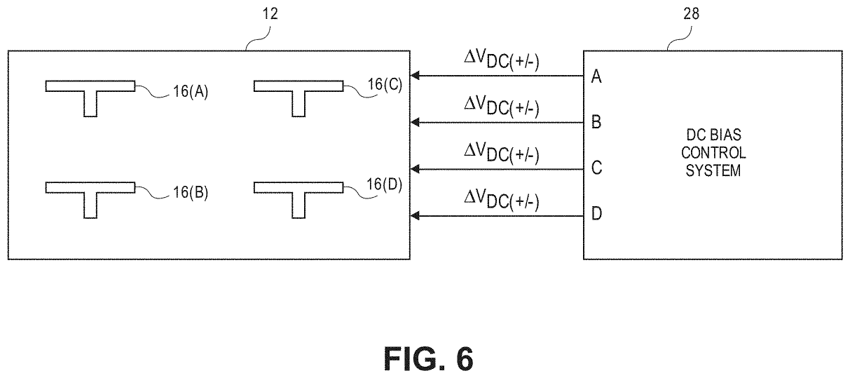

Referring to FIG. 6 a diagram of a CVD chamber 12 having multiple substrate pedestals 16 is illustrated. In this particular embodiment, the CVD tool 10 is referred to as a “quad” tool because it has four substrate pedestals 16A-16D in the processing chamber 12. The DC bias control system 28 therefore provides four (A-D) bias voltages ΔV_{DC} (+/−), each calculated as described above for the four substrate pedestals 16A-16D respectively. It should be understood that the quad tool 10 as illustrated is merely exemplary and should not be construed as limiting in a manner. The system for suppressing or eliminating arcing may be used in a CVD tool having any number of substrate pedestals.

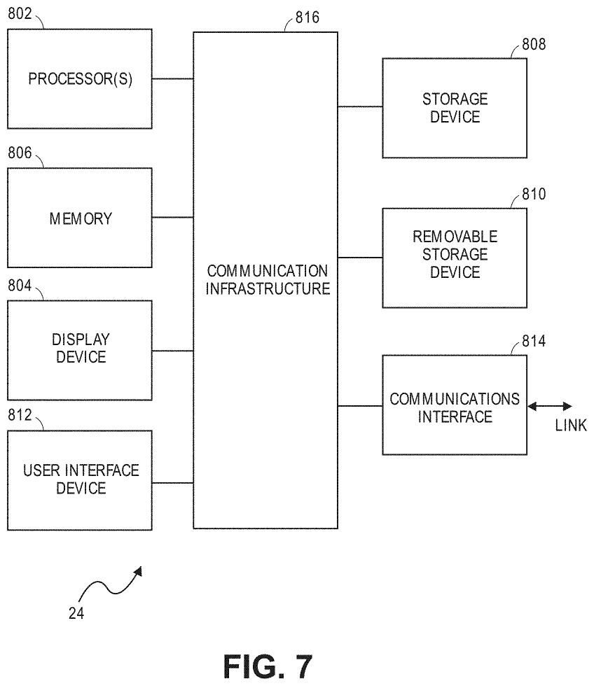

FIG. 7 is a high level block diagram showing the system controller 24. The computer system 24 may have many physical forms ranging from an integrated circuit, a printed circuit board, a small handheld device, personal computer, server, a super computer, any of which may have one or multiple processors. The computer system 24 further can include an electronic display device 804 (for displaying graphics, text, and other data), a non-transient main memory 806 (e.g., random access memory (RAM)), storage device 808 (e.g., hard disk drive), removable storage device 810 (e.g., optical disk drive), user interface devices 812 (e.g., keyboards, touch screens, keypads, mice or other pointing devices, etc.), and a communication interface 814 (e.g., wireless network interface). The communication interface 814 allows software and data to be transferred between the system controller 24 and external devices via a link. The system controller 24 may also include a communications infrastructure 816 (e.g., a communications bus, cross-over bar, or network) to which the aforementioned devices/modules are connected.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals.

In certain embodiments, the system controller 24, running or executing the system software or code, controls all or at least most of the activities of the tool 10, including such activities as controlling the timing of the processing operations, frequency and power of operations of the RF generator 20, pressure within the processing chamber 12, flow rates, concentrations and temperatures of gas(es) into the process chamber 12 and their relative mixing, temperature of a substrate 18 supported by the substrate holder 16, etc.

Information transferred via communications interface 814 may be in the form of signals such as electronic, electromagnetic, optical, or other signals capable of being received by communications interface 814, via a communication link that carries signals and may be implemented using wire or cable, fiber optics, a phone line, a cellular phone link, a radio frequency link, and/or other communication channels. With such a communications interface, it is contemplated that the one or more processors 802 might receive information from a network, or might output information to the network. Furthermore, method embodiments may execute solely upon the processors or may execute over a network such as the Internet, in conjunction with remote processors that shares a portion of the processing.

It should be understood that the embodiments provided herein are merely exemplary and should not be construed as limiting in any regard. In general, the present application is intended to cover any a shower head having at least two set of holes defining two spiral patterns and two plenums for the two patterns respectfully.

Although only a few embodiments have been described in detail, it should be appreciated that the present application may be implemented in many other forms without departing from the spirit or scope of the disclosure provided herein. For instance, the substrate can be a semiconductor wafer, a discrete semiconductor device, a flat panel display, or any other type of work piece.

Therefore, the present embodiments should be considered illustrative and not restrictive and is not to be limited to the details given herein, but may be modified within the scope and equivalents of the appended claims.

1. A Chemical Vapor Deposition (CVD) tool, comprising
a processing chamber;
a substrate pedestal for supporting a substrate within the processing chamber;
a shower head positioned within the processing chamber, the shower head arranged to dispense gas that is turned into a plasma within the processing chamber in response to a Radio Frequency (RF) potential, the plasma developing a DC bias voltage; and
a Direct Current (DC) bias control system arranged to maintain the substrate pedestal at a same or substantially the same DC bias voltage as the DC bias voltage developed by the plasma in the processing chamber.

2. The CVD tool of claim 1, wherein the DC bias control system is further arranged to adjust the DC bias voltage of the substrate pedestal as the DC bias voltage developed by the plasma changes.

3. The CVD tool of claim 2, wherein the DC bias control system adjusts the DC bias voltage of the substrate pedestal by:
measuring current along a current path between the plasma and an electrode; and
adjusting the DC bias voltage of the substrate pedestal so that the measured current is maintained at zero or at a constant predetermined value.

4. The CVD tool of claim 3, wherein the DC bias control system is further arranged to use the measured current as a set point at initiation of processing of the substrate and to adjust the DC bias voltage of the substrate pedestal during subsequent processing of the substrate.

5. The CVD tool of claim 3, wherein the current path between the plasma and the electrode includes one or more of the following:
(a) the substrate supported by the substrate pedestal;
(b) any thin film(s) formed on the substrate;
(c) electrodes provided on the substrate pedestal;
(d) a power supply couple to the substrate pedestal; and
(e) the substrate pedestal.

6. The CVD tool of claim 3, wherein a resistive value along the current path is derived from one or more of the following:
(a) the substrate;
(b) any thin film(s) formed on the substrate;
(c) electrodes provided on the substrate pedestal; and
(d) a power supply couple to the substrate pedestal.

7. The CVD tool of claim 1, wherein the substrate pedestal is an Electrostatic Chuck (ESC) type substrate pedestal including first and second electrodes maintained at opposing clamping potentials, wherein the opposing clamping potentials are adjusted by the same or substantially the same DC bias voltage as developed by the plasma in the processing chamber.

8. The CVD tool of claim 1, wherein the substrate pedestal includes an RF electrode for providing the RF potential to the plasma in the processing chamber.

9. The CVD tool of claim 8, wherein the RF electrode is adjusted by the same or substantially the same DC bias voltage as developed by the plasma in the processing chamber.

10. The CVD tool of claim 1, wherein the DC bias control system includes:
a current measurement device for measuring current between the plasma and an electrode; and
a controlled power supply, responsive to the current measurement device, for generating a controlled DC bias voltage applied to electrodes provided on the substrate pedestal, the controlled DC bias voltage maintaining the substrate pedestal at the same or substantially the same DC bias voltage as the DC bias voltage developed by the plasma in the processing chamber.

11. The CVD tool of claim 7, wherein the first and second electrodes provided on the substrate pedestal are positive and negative electrodes used for electro-statically clamping the substrate to the substrate pedestal.

12. The CVD tool of claim 1, wherein the processing chamber further includes two or more substrate pedestals.

13. The CVD tool of claim 14, wherein the DC bias control system is further arranged to maintain the two or more substrate pedestals at the same or substantially the same DC bias voltage as the plasma in the processing chamber.

14. The CVD tool of claim 1, wherein substantially the same means the DC bias voltage developed by the plasma and the substrate pedestal have voltage differential of 10.0 volts or less.

15. The CVD tool of claim 1, wherein substantially the same means the DC bias voltage developed by the plasma and the substrate pedestal have voltage differential of 0.1 volts or less.

16. A Chemical Vapor Deposition (CVD) tool comprising a Direct Current (DC) bias control system arranged to maintain a substrate pedestal provided in a processing chamber at a same or substantially the same DC bias voltage as developed by a plasma in the processing chamber.

17. The CVD tool of claim 16, wherein the substrate pedestal includes Electrostatic Clamp (ESC) electrodes of opposing polarity for clamping a substrate to the substrate pedestal and the DC bias voltage is applied to the ESC electrodes.

18. The CVD tool of claim 16, wherein the DC bias control system adjusts the DC bias voltage as the DC bias voltage developed by the plasma changes in the processing chamber.

19. The CVD tool of claim 16, wherein the DC bias control system includes
a current measurement device for measuring current between the plasma and an electrode;
an power supply for applying a DC bias offset to electrodes provided on the substrate pedestal, the DC bias offset commensurate with the measured current.

20. The CVD tool of claim 19, wherein a current path for the current between the plasma and the electrode includes one or more of the following:
(a) a substrate supported by the substrate pedestal;
(b) any thin film(s) formed on the substrate;
(c) electrodes provided on the substrate pedestal;
(d) a power supply couple to the substrate pedestal; and
(e) the substrate pedestal.

21. The CVD tool of claim 19, wherein a resistive value between the plasma and an electrode is derived from a resistance of one or more of the following:
(a) a substrate;
(b) any thin film(s) formed on the substrate;
(c) electrodes provided on the substrate pedestal; and
(d) a power supply couple to the substrate pedestal.

22. The CVD tool of claim 16, wherein substantially the same means the DC bias voltage developed by the plasma and the substrate pedestal have voltage differential of 10.0 volts or less.

23. The CVD tool of claim 16, wherein substantially the same means the DC bias voltage developed by the plasma and the substrate pedestal have voltage differential of 0.1 volts or less.
